(19) United States
(12) Patent Application Publication
(10) Pub. No.: US 2014/0368279 A1
(43) Pub. Date: Dec. 18, 2014

(54) Direct Biasing A Gate Electrode Of A Radio Frequency Power Amplifier Through a Driver Stage

(71) Applicant: Auriga Measurement Systems, LLC, Chelmsford, MA (US)

(72) Inventor: Yusuke Tajima, Acton, MA (US)

(73) Assignee: AURIGA MEASUREMENT SYSTEMS, LLC, Chelmsford, MA (US)

(21) Appl. No.: 14/308,034

(22) Filed: Jun. 18, 2014

Related U.S. Application Data
(60) Provisional application No. 61/836,257, filed on Jun. 18, 2013.

(51) Int. Cl. H03F 3/20; H03F 3/193

(52) U.S. Cl. CPC H03F 3/20; H03F 3/193; H03F 2200/451; H03F 2200/522
USPC 330/296

(57) ABSTRACT

A radio frequency (RF) circuit includes an amplifier circuit comprising at least one transistor amplifier having first, second, and third terminals. The RF circuit additionally includes a driver circuit comprising an enhancement-mode transistor and a depletion-mode transistor coupled in a cascade configuration having an upper portion and a lower portion, the driver circuit having an output coupled to an input of the amplifier circuit such that the driver circuit is capable of providing pulsed signals as well as a direct-current (DC) bias current to at least one terminal of a transistor amplifier of the amplifier circuit. A corresponding method is also provided.

### CROSS REFERENCE TO RELATED APPLICATIONS

The present application claims the benefit of U.S. Provisional Application No. 61/836,257, filed on Jun. 18, 2013, which is hereby incorporated by reference herein in its entirety.

### STATEMENT REGARDING FEDERALLY SPONSORED RESEARCH

Not Applicable.

### FIELD

This disclosure relates generally to radio frequency (RF) circuits and, more particularly, to techniques and circuits for use in operating a radio frequency (RF) power amplifier.

### BACKGROUND

As is known in the art, conventional radio frequency (RF) amplifier circuits generally include a power amplifier (e.g., low-impedance RF power amplifier) for amplifying RF signals and driver circuitry for driving the power amplifier. Typically, the driver circuitry drives the power amplifier with pulses such that the power amplifier generates RF signals as outputs.

In modern RF amplifier circuit applications, it is desirable to have driver circuitry that is capable of not only driving the power amplifier with pulses but also capable of generating and providing a bias current to the power amplifier.

### SUMMARY

In one aspect, a radio frequency (RF) circuit includes an amplifier circuit including at least one transistor amplifier having first, second, and third terminals. The RF circuit additionally includes a driver circuit comprising an enhancement-mode transistor and a depletion-mode transistor coupled in a cascade configuration using the enhancement-mode transistor in an upper portion and depletion-mode transistor in a lower portion, the driver circuit having an output coupled to an input of the amplifier circuit such that the driver circuit is capable of providing pulsed signals as well as a direct-current (DC) bias voltage to at least one terminal of a transistor amplifier of the amplifier circuit. The enhancement-mode transistor has a terminal coupled to a supply voltage and the depletion-mode transistor has a terminal coupled to a reference voltage such that the output pulse signal will have two levels between the supply voltage and the reference voltage.

Features of the RF circuit may include one or more of the following either individually or in combination. The enhancement-mode transistor is provided on the upper portion of the cascode configuration and the depletion-mode transistor is provided on the lower portion of the cascode configuration. The enhancement-mode transistor is provided having a substantially greater current capacity than the depletion-mode transistor. The driver circuit is configured to provide pulses switching between two levels. The driver circuit may include multiple enhancement-mode transistors and multiple depletion-mode transistors coupled in the cascade configuration. The driver circuit output is directly coupled to the input terminal of the amplifier circuit without use of an intervening DC blocking capacitor.

Features of the circuit may further include one or more of the following either individually or in combination. A drain terminal of the enhancement mode transistor is coupled to a first supply voltage node, a source terminal of the enhancement mode transistor is coupled to the output of the driver circuit, the drain terminal of the depletion mode transistor is coupled to the output of the driver circuit, and the source node of the depletion mode transistor is coupled to a second supply voltage (reference voltage) node, wherein the driver circuit is configured to generate pulses at the output thereof that have a substantially constant voltage levels between the supply voltage and the reference voltage. The amplifier circuit may be provided as a power amplifier (PA) and the enhancement-mode transistor has a current characteristic such that the enhancement-mode transistor is capable of providing enough current to operate the PA when the enhancement-mode transistor is in an active state. The depletion-anode transistor will be pinched-off when the enhancement-mode transistor is in an active state; therefore the output is isolated from the reference voltage. When the enhancement-mode device is switched to non-active state (pinched-off), the depletion-mode will be turned on (active state) and the reference voltage will be provided to the PA. The reference voltage will set the PA in non-active (pinched-off) condition. Not much current is required from the depletion-mode device. With this configuration, the PA will be switched between active and non-active by the pulse signal applied to the gate of the PA which switches between the supply voltage and reference voltage.

In one aspect, a driver circuit for driving a power amplifier includes one or more enhancement-mode field effect transistors having a gate terminal, a source terminal and a drain terminal, wherein the gate terminals of one or more of the enhancement-mode field effect transistors are coupled to a first input of the driver circuit and the drain terminals of one or more of the enhancement-mode field effect transistors are coupled to a supply voltage. The driver circuit additionally includes one or more depletion-mode field effect transistors having a gate terminal, a source terminal and a drain terminal, wherein the gate terminals of one or more of the depletion-mode field effect transistors are coupled to a second input of the driver circuit, the source terminals of one or more of the depletion-mode field effect transistors are coupled to a reference potential, and the drain terminals of one or more of the depletion-mode field effect transistors are coupled to the source terminals of one or more of the enhancement-mode field effect transistors to form a driver circuit output. The enhancement-mode transistors and the depletion-mode transistors are coupled in a cascode configuration having an upper portion and a lower portion, wherein the enhancement-mode transistors are provided on the upper portion and the depletion-mode transistors are provided on the lower portion.

Features of the driver circuit may include one or more of the following either individually or in combination. In one embodiment, the reference potential is ground. In one embodiment, the reference potential is not ground, but attached to the second supply voltage. In one embodiment, the first and second inputs of the driver circuit are coupled to receive first and second differential switched signals for configuring the one or more enhancement-mode transistors and one or more depletion-mode transistors to an active or inactive state, wherein the active state corresponds to an on state and the inactive state corresponds to an off state.

In another aspect, a method of driving an amplifier circuit includes receiving first and second differential switched signals at first and second inputs of a driver circuit, wherein the driver circuit comprises one or more enhancement-mode transistors and one or more depletion-mode transistors coupled in a cascode configuration having an upper portion and a lower portion, wherein a terminal of one or more of the enhancement-mode transistors is coupled to a supply voltage and a terminal of one or more of the depletion-mode transistors is coupled to a reference potential.

Features of the method may include one or more of the following either individually or in combination. The enhancement-mode transistors are provided on the upper portion of the cascade configuration and the depletion-mode transistors are provided on the lower portion of the cascode configuration. The enhancement-mode transistors and the depletion-mode transistors are provided as field effect transistors (FETs) having a gate terminal, a source terminal and a drain terminal.

In one aspect, a radio frequency (RF) circuit includes an RF amplifier to amplify a signal applied to an input terminal thereof. The RF circuit additionally includes a driver circuit to provide pulsed drive signals to the input terminal of the RF amplifier.

### BRIEF DESCRIPTION OF THE DRAWINGS

The foregoing features of the disclosure, as well as the disclosure itself may be more fully understood from the following detailed description of the drawings, in which:

FIG. 1 is a block diagram of a conventional amplifier circuit; and

FIG. 2 is a block diagram of an example amplifier circuit in accordance with an embodiment.

### DETAILED DESCRIPTION

The features and other details of the concepts, systems, circuits and techniques sought to be protected herein will now be more particularly described. It will be understood that any specific embodiments described herein are shown by way of illustration and not as limitations of the disclosure. The principal features of this disclosure can be employed in various embodiments without departing from the scope of the concepts sought to be protected. Embodiments of the present disclosure and associated advantages may be best understood by referring to the drawings, where like numerals are used for like and corresponding parts throughout the various views,

### Definitions

For convenience, certain introductory concepts and terms used in the specification are collected here.

As used herein, the term “processor” is used to describe an electronic circuit that performs a function, an operation, or a sequence of operations. The function, operation, or sequence of operations can be hard coded into the electronic circuit or soft coded by way of instructions held in a memory device. A “processor” can perform the function, operation, or sequence of operations using digital values or using analog signals.

In some embodiments, the “processor” can be embodied, for example, in a specially programmed microprocessor, a digital signal processor (DSP), or an application specific integrated circuit (ASIC), which can be an analog ASIC or a digital ASIC. Additionally, in some embodiments the “processor” can be embodied in configurable hardware such as field programmable gate arrays (FPGAs) or programmable logic arrays (PLAs). In some embodiments, the “processor” can also be embodied in a microprocessor with associated program memory. Furthermore, in some embodiments the “processor” can be embodied in a discrete electronic circuit, which can be an analog or digital.

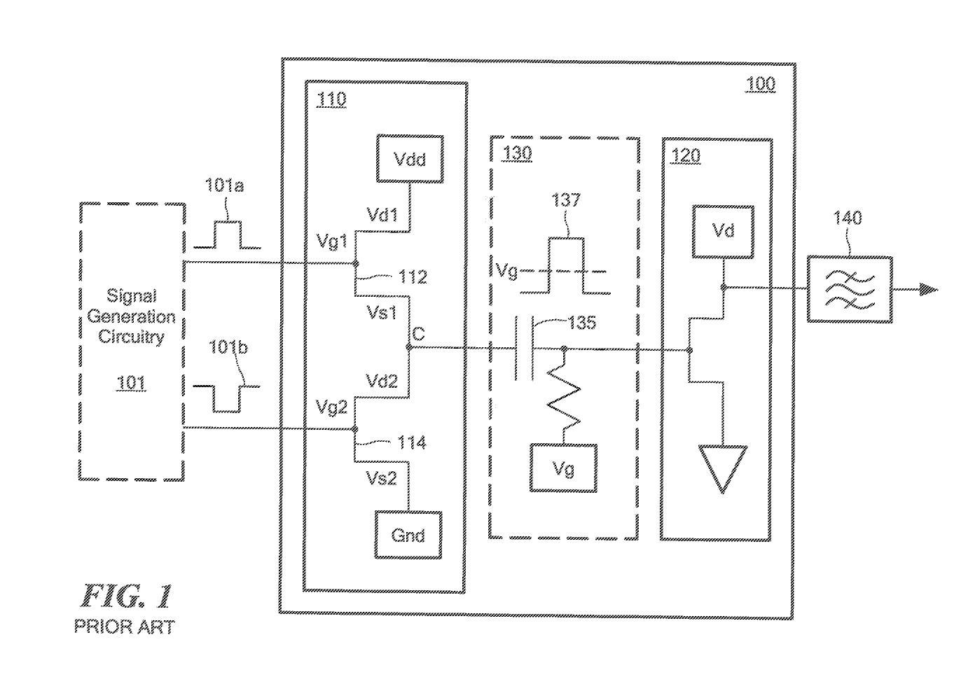

Referring now to FIG. 1, a conventional amplifier circuit 100 for amplifying radio frequency (RF) signals includes a driver circuit 110 comprising depletion-mode field-effect transistors (FETs) 112, 114 and a power amplifier (PA) circuit 120. The amplifier circuit 100 also includes bias circuitry 130 coupled between the driver circuit 110 and the PA circuit 120. As shown in FIG. 1, amplifier circuit 100 may also include signal generation circuitry 101, which may be coupled to input terminals of the amplifier circuit 100 to provide input signals thereto. In this example amplifier circuit 100, the signal generation circuitry 101 and the bias circuitry 130 are not a part of the amplifier circuit 100 and are thus shown in phantom lines.

The signal generation circuitry 101 generates first and second differential switching signals 101a, 101b at outputs thereof. The first and second differential switching signals 101a, 101b are representative of control signals for controlling a state of the driver circuit 110 (e.g., operation of each transistor included in the driver circuit 110). As is known in the art, depletion-mode FETs are “normally-on” devices acting as “normally-closed” switches, requiring substantially no gate current to function. As is also known, depletion-mode FETs are turned off by “pulling” the FET gate negative.

The driver circuit 110, which includes first and second depletion-mode (or cascade) FETs 112, 114 arranged in a cascade configuration (in first and second cascade stages, upper and lower stages respectively), has first and second inputs coupled to the first and second outputs of the signal generation circuitry 101. The first cascade FET 112 has a gate terminal (or “electrode”) (G1) coupled to the first cascade driver stage input, a drain terminal (D1) coupled to a supply voltage (Vdd), and a source terminal (S1) coupled to a drain terminal (D2) of the second cascade FET 114 at a node C. The second cascade FET 114 has a gate terminal (G2) coupled to the second cascade driver stage input, a drain terminal (D2) coupled to the source terminal (S1) of the first cascade FET 112 at node C, and body and source terminals (S2) coupled to a reference potential (i.e., ground).

The first and second cascade FETs 112, 114 receive the first and second differential switching signals 101a, 101b at their respective gate terminals (G1, G2) as inputs and in response thereto produce a pulsed output signal at node C. Node C is coupled to an output of driver circuit 10. In general, the pulsed output signal at node C will be switched between two levels, Vdd (e.g., 5V) and 0 V, through switching of the first and second cascade FETs 112, 114 by first and second differential switching signals 101a, 101b. Since the voltage range (e.g., 0V-5V) produced by the first and second cascade FETs 112, 114 is not necessarily a voltage range that the PA circuit 120 is designed for, biasing circuitry 130 is coupled between an output of driver circuit 110 and an input of PA circuit 120 for properly biasing the PA circuit 20.

In the illustrated arrangement, the biasing circuitry 130 is shown having inputs coupled to the driver circuit output. Additionally, the biasing circuitry 130 is shown having a direct-current (DC) blocking capacitor 135 and a bias voltage Vg. The biasing circuitry 130 receives the pulsed output signal of the driver circuit 110 and in response thereto provides the pulsed output signal to the DC blocking capacitor 135. The DC blocking capacitor 135 removes the DC component of the pulsed output signal. The bias voltage Vg is coupled to add a DC level to the pulsed output signal that the pulsed output signal is subsequently substantially symmetric around the bias voltage Vg. As such, the bias voltage Vg sets the average voltage (or mid-point) of the pulsed output signal, as shown in pulse 137.

The PA circuit 120 has an input coupled to the biasing circuitry output. The PA circuit 120 receives the pulsed output signal that is substantially symmetric around the bias voltage Vg at an input thereof and in response thereto generates an amplified pulsed signal at an output thereof. The PA circuit output, in the embodiment shown, is coupled to an input of a filter circuit 140. The filter circuit 140 can, for example, be a low-pass filter. The filter circuit 140 receives the amplified pulsed signal at an input thereof and in response thereto generates a modulated RF signal at an output thereof. The modulated RF signal is provided reflecting the pulse modulation associated with the received amplified pulsed signal. More particularly, the filter circuit 140 removes high frequency content from the amplified output signal of the PA circuit 120 to generate an RF signal (sinusoid).

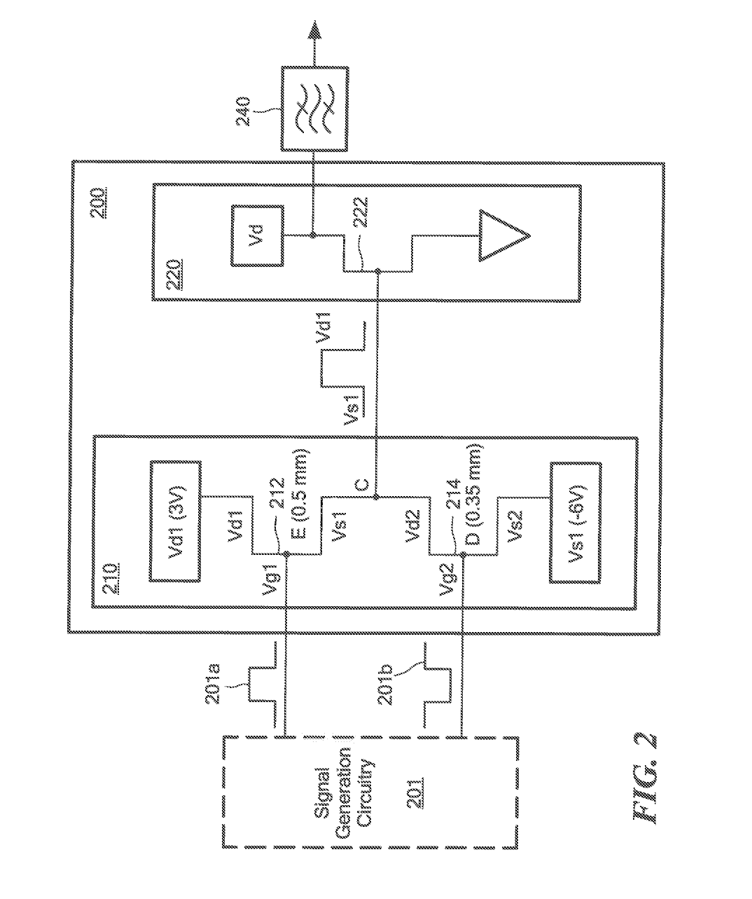

Referring now to FIG. 2, an example amplifier circuit 200 for generating RF signals from pulsed signals includes a driver circuit 210 comprising both depletion-mode and enhancement-mode FETs 212, 214 and a power amplifier (PA) circuit 220, which in the embodiment shown is a low-impedance PA circuit 220. The amplifier circuit 200 can, for example, be an RF amplifier operating in accordance with a pulse-width modulation (PWM) scheme. In one embodiment, the depletion-mode and enhancement-mode FETs 214, 212 (or first and second cascode FETs 212, 214) are N and P type metal-oxide-semiconductor field-effect transistors (MOSFETs). The amplifier circuit 200 also includes signal generation circuitry 201 coupled as shown. In this example embodiment, the signal generation circuitry 201 is not a part of the amplifier circuit 200 and is thus shown in phantom lines. It should, of course, be appreciated that in other embodiments the signal generation circuitry 201 may be provided as part of the amplifier circuit 200. It should also be appreciated that the functionality provided by each of the signal generation circuitry 201, the driver circuit 210 and the PA circuit 220 may be shared or split other than as Illustrated in FIG. 2.

The signal generation circuitry 201 generates first and second differential switching signals 201a, 201b at outputs thereof. The first and second differential switch signals 201a, 201b are representative of control signals for controlling a state of the driver circuit 210 (e.g., operation of each transistor included in the driver circuit 210, here first and second cascade FETs 212, 214). In the example embodiment shown, the first and second differential switch signals 201a, 201b are provided as pulsed signals alternating between two reference potentials corresponding to potentials necessary to turn the first and second cascade FETs 212, 214 to respective off and on states. The signal generation circuitry 201 can, for example, be controlled by a processor (not shown) coupled to or included within the amplifier circuit 200, but it is not so limited. In one embodiment, the signal generation circuitry 201 is provided as a processor. As is known in the art, enhancement-mode transistors are “normally-off” devices that are turned on by pulling the gate voltage in the direction of a supply voltage.

The driver circuit 210, which includes the first cascade FET 212 and the second cascade FET 214 arranged in a cascade configuration in the example embodiment shown, and can comprise one or more enhancement-mode FETs and one or more depletion-mode FETs in a corresponding cascade configuration in other embodiment (in such embodiment the additional FETs would be connected in parallel to each other), has first and second inputs coupled to the first and second outputs of the signal generation circuitry 201. The first cascade FET (or upper device in “cascode stage”) 212, an enhancement-mode FET (E), has a gate terminal (G1) coupled to the first cascade stage input, a drain terminal (D1) coupled to a supply voltage (Vd1), and a source terminal (S1) coupled to a drain terminal (D2) of the second cascade FET (or lower device in the “cascade stage”) 214 at a node C. The second cascade FET 214, a depletion-mode FET, has a gate terminal (G2) coupled to the second cascade stage input, a drain terminal (D2) coupled to the body and source terminals (S1) of the first cascade FET 212 at node C, and a source terminal (S2) coupled to a reference potential. In this example embodiment, the reference potential is shown as 6V, but it is not so limited.

In this example embodiment, the cascade configuration is shown having an upper portion (or “high side”) and a lower power (or “low side”) with the first cascade FET 212 provided on the high side (i.e., as a high side FET) and the second cascade FET 214 provided on the low side (i.e., as a low side FET), but it is not so limited.

The first and second cascade FETs 212, 214 receive the first and second differential switching signals 201a, 201b at their respective gate terminals (G1, G2) as inputs and in response thereto the first and second cascade FETs 212, 214 are switched alternatively to generate a pulsed output signal having an associated drive current and a direct-current (DC) bias voltage at node C. Node C is coupled to an output of driver circuit 210. The pulsed output signal, in the illustrated arrangement, is a pulsed signal comprising pulses of RF energy. In one embodiment, the pulsed output signals comprises a potential between Vs1 and Vd1, where Vs1 is a required voltage to turn off a PA FET (or transistor amplifier) 222 associated with the PA circuit 220 and Vd1 is a required voltage to turn on the PA FET 222. The PA FET 222 has first, second and third terminals in the example embodiment shown.

In one embodiment, when the pulsed output signal is in an on (or active) state, bias current is provided to the PA circuit 220 through the high side device (i.e., the first cascade FET 212). In this example embodiment, the high side device (i.e., the first cascade FET 212) provides enough current to drive the PA circuit 220, which is coupled to node C. In one embodiment, the size of the high side device (i.e., the first cascade FET 212) is selected not to limit the current draw by its maximum current. Conventionally, large FETs designed for power switching have a substantially lower “an-resistance” than smaller FETs, and comprise a higher current capability.

In one embodiment, when the pulsed output signal is in an off (or inactive) state, bias current is provided to the PA circuit 220 through the low side device (i.e., the second cascade FET 214). In this embodiment, the low side device (i.e., the second cascode FET 214) is turned on and the high side device (i.e., the first cascode FET 212) is turned off. Under this setting, the pulsed output signal (with a small amount of drive current) is provided to the PA circuit 220 from the low side device (i.e., the second cascode FET 214), providing the reference voltage (i.e., Vs1) to the PA circuit 220, setting the PA FET 222 at a nominally off condition. The current drive necessary for the PA FET 222 at normally off condition is small, thus low side device (i.e., the second cascade FET 214) can be substantially smaller than the high side device (i.e., the first cascode FET 212).

The PA circuit 220 has an input coupled to the driver circuit output. In one embodiment, the PA FET 222 is provided as a FET having drain, gate and source terminals as the first, second, and third terminals with the drain terminal coupled to the amplifier bias supply Vd and the source terminal being coupled to ground. The PA circuit 220 receives the pulsed output signal at an input thereof and in response thereto generates an amplified pulse signal at an output thereof. The PA circuit output, in the embodiment shown, is coupled to an input of a filter circuit 240. The filter circuit 240, like filter circuit 140 of FIG. 1, can be a low-pass filter. The filter circuit 240 receives the amplified pulsed signal at an input thereof and in response thereto generates a modulated RF signal at an output thereof. The modulated RF signal is provided reflecting the pulse modulation associated with the received amplified pulsed signal. More particularly, the filter circuit 240 removes high frequency content from the amplified output signal of the PA circuit 220 to generate an RF signal (sinusoid). The reference voltage (i.e., Vs1), which according to some embodiments is the floor of the pulse output signal, is intended to place the PA circuit 220 in a non-active condition when the pulsed output signal is in an off (or inactive) state.

In one embodiment, the pulsed output signal and DC bias voltage are received by at least one of the first, second and third terminals of the PA FET 222. In another embodiment, the pulsed output signal and DC bias voltage are received by only the gate terminal of the PA FET 222. The PA circuit 220 is driven between a supply voltage (i.e., Vd1), which is of a high current, and reference voltage (i.e., Vs1), which is of a low current, in pulsed operation such that the PA circuit 220 is operating at an optimum efficiency level. As illustrated above, no biasing circuitry (e.g., biasing circuitry 130 of FIG. 1) is needed for biasing the PA circuit 220. As will be appreciated, the lack of biasing circuitry within amplifier circuit 200 means there will be no performance degradation caused by bias circuit mismatches.

Having described preferred embodiments which serve to illustrate various concepts, circuits, and techniques which are the subject of this patent, it will now become apparent to those of ordinary skill in the art that other embodiments incorporating these concepts, circuits, and techniques may be used. For example, described herein is a specific example circuit topology and specific circuit implementation for achieving a desired performance. It is recognized, however, that the concepts and techniques described herein may be implemented using other circuit topologies and specific circuit implementations. Accordingly, it is submitted that that scope of the patent should not be limited to the described embodiments but rather should be limited only by the spirit and scope of the following claims,

What is claimed is:

1. A radio frequency (RF) circuit comprising:
an amplifier circuit including at least one transistor amplifier having first, second, and third terminals; and
a driver circuit including an enhancement-mode transistor and a depletion-mode transistor coupled in a cascade configuration having an upper portion and a lower portion, the driver circuit having an output coupled to an input of the amplifier circuit such that the driver circuit is capable of providing pulsed signals as well as a direct-current (DC) bias current to at least one terminal of a transistor amplifier of the amplifier circuit.

2. The RF circuit of claim 1 wherein the enhancement-mode transistor is provided on the upper portion of the cascade configuration and the depletion-mode transistor is provided on the lower portion of the cascade configuration.

3. The RF circuit of claim 1 wherein the enhancement-mode transistor is provided having a substantially greater current capacity than the depletion-mode transistor.

4. The RF circuit of claim 1 wherein the amplifier circuit is a power amplifier circuit for use with pulse width modulation enhancement.

5. The RF circuit of claim 1 wherein the amplifier circuit has an output coupled to an input of a filter circuit, wherein the filter circuit is capable of removing high frequency content from an amplified output signal generated by and received from the amplifier circuit to generate an RF signal.

6. The RF circuit of claim 1 wherein the driver circuit includes multiple enhancement-mode transistors and multiple depletion-mode transistors coupled in the cascade configuration.

7. The RF circuit of claim 1 wherein the driver circuit output is directly coupled to the input terminal of the amplifier circuit without use of an intervening DC blocking capacitor.

8. The RF circuit of claim 1 wherein a drain terminal of the enhancement mode transistor is coupled to a first supply voltage node, a source terminal of the enhancement mode transistor is coupled to the output of the driver circuit, the drain terminal of the depletion mode transistor is coupled to the output of the driver circuit, and the source node of the depletion mode transistor is coupled to a second supply voltage node, wherein the driver circuit is configured to generate pulses at the output thereof that have a substantially constant voltage pulse floor at the voltage level of the second supply voltage node.

9. The RF circuit of claim 1 wherein the amplifier circuit is provided as a power amplifier (PA) circuit and the enhancement-mode transistor has a current characteristic such that the enhancement-mode transistor is capable of providing enough current to operate the PA circuit when the enhancement-mode transistor is in an active state.

10. The RF circuit of claim 9 wherein the depletion-mode transistor is biased down to a first reference voltage such that the depletion-mode transistor is capable of providing a nominally off condition for the PA circuit when the depletion-mode transistor is configured in an inactive state.

11. A driver circuit for driving a power amplifier, the driver circuit comprising:
one or more enhancement-mode field effect transistors having a gate terminal, a source terminal and a drain terminal, wherein the gate terminals of one or more of the enhancement-mode field effect transistors are coupled to a first input of the driver circuit and the drain terminals of one or more of the enhancement-mode field effect transistors are coupled to a supply voltage; and
one or more depletion-mode field effect transistors having a gate terminal, a source terminal and a drain terminal, wherein the gate terminals of one or more of the depletion-mode field effect transistors are coupled to a second input of the driver circuit, the source terminals of one or more of the depletion-mode field effect transistors are coupled to a reference potential, and the drain terminals of one or more of the depletion-mode field effect transistors are coupled to the source terminals of one or more of the enhancement-mode field effect transistors to form a driver circuit output,
wherein the enhancement-mode transistors and the depletion-mode transistors are coupled in a cascode configuration having an upper portion and a lower portion, wherein the enhancement-mode transistors are provided on the upper portion and the depletion-mode transistors are provided on the lower portion.

12. The driver circuit of claim 11 wherein the reference potential is ground.

13. The driver circuit of claim 11 wherein the reference potential is not ground.

14. The driver circuit of claim 11 wherein the first and second inputs of the driver circuit are coupled to receive first and second differential switched signals for configuring the one or more enhancement-mode transistors and one or more depletion-mode transistors to an active or inactive state, wherein the active state corresponds to an on state and the inactive state corresponds to an off state.

15. A method of driving an amplifier circuit, comprising:
receiving first and second differential switched signals at first and second inputs of a driver circuit, wherein the driver circuit comprises one or more enhancement-mode transistors and one or more depletion-mode transistors coupled in a cascode configuration having an upper portion and a lower portion, wherein a terminal of one or more of the enhancement-mode transistors is coupled to a supply voltage and a terminal of one or more of the depletion-mode transistors is coupled to a reference potential;
generating a driver signal at an output of the driver circuit; and
providing the driver signal to an input of the amplifier circuit.

16. The method of claim 15 wherein the enhancement-mode transistors are provided on the upper portion of the cascode configuration and the depletion-mode transistors are provided on the lower portion of the cascode configuration.

17. The method of claim 15 wherein the enhancement-mode transistors and the depletion-mode transistors are provided as field effect transistors (FETs) having a gate terminal, a source terminal and a drain terminal.

18. The method of claim 15 wherein receiving first and second differential switched signals at first and second inputs of a driver circuit further comprises:
configuring the one or more enhancement-mode transistors and one or more depletion-mode transistors to an active or inactive state based upon the first and second differential switched signals, wherein the active state corresponds to an on state and the inactive state corresponds to an off state.

19. The method of claim 16, further comprising:
generating an amplified output signal in response to the driver signal;
providing the amplified output signal to an input of a filter circuit; and
removing high frequency content from an amplified output signal to generate an RF signal at an output of the filter circuit.
